(19) United States
(12) Patent Application Publication
(10) Pub. No.: US 2025/0273465 A1
(43) Pub. Date: Aug. 28, 2025

(54) MASK AND METHOD OF MANUFACTURING SEMICONDUCTOR DEVICE USING THE SAME

(71) Applicant: SK hynix Inc., Icheon-si Gyeonggi-do (KR)

(72) Inventors: Woo Sung MOON, Icheon-si Gyeonggi-do (KR); Joon Seuk LEE, Icheon-si Gyeonggi-do (KR); Do Yeon KIM, Icheon-si Gyeonggi-do (KR); Young Rok KIM, Icheon-si Gyeonggi-do (KR)

(73) Assignee: SK hynix Inc., Icheon-si Gyeonggi-do (KR)

(21) Appl. No.: 18/774,384

(22) Filed: Jul. 16, 2024

(30) Foreign Application Priority Data
Feb. 22, 2024 (KR) 10-2024-0025730

(51) Int. Cl. H01L 21/027; H01L 21/033; H01L 21/311; H01L 21/3213; H01L 23/544

(52) U.S. Cl. CPC H01L 21/0274; H01L 21/0334; H01L 21/31144; H01L 21/32139; H01L 23/544; H01L 2223/54426; H01L 2223/5446

(57) ABSTRACT

The method may include forming a photoresist over a first structure, forming a photoresist pattern by removing a portion of the photoresist through a mask including a mask opening, wherein the mask opening includes a light-blocking pattern and a light-transmitting area, forming, by etching the first structure according to the photoresist pattern, a target opening corresponding to the mask opening and an auxiliary pattern corresponding to the light-blocking pattern of the mask opening, wherein the target opening is formed to have a first depth, wherein the auxiliary pattern is formed to have a second depth that is shallower than the first depth, and wherein the auxiliary pattern is located in the target opening and is implemented as a part of the first structure, and forming an alignment key by removing the auxiliary pattern from within the target opening.

### CROSS-REFERENCE TO RELATED APPLICATION

The present application claims priority under 35 U.S.C. § 119(a) to Korean patent application number 10-2024-0025730 filed on Feb. 22, 2024, in the Korean Intellectual Property Office, the entire contents of which application is incorporated herein by reference.

### BACKGROUND

### 1. Technical Field

Various embodiments of the present disclosure generally relate to a mask and a method of manufacturing a semiconductor device using the mask, and more particularly to a method of manufacturing a semiconductor device through a lithography process using a mask.

### 2. Related Art

Through a semiconductor integration process, a plurality of chip areas may be formed on a semiconductor substrate. The plurality of chip areas may be distinguished from each other by using a scribe lane area as a boundary. The plurality of chip areas may be separated through a cutting process, and thus, a plurality of semiconductor chips may be manufactured from the chip areas.

Meanwhile, an alignment key may be used to align a layer that is newly formed over a predetermined location of the semiconductor substrate when the semiconductor integration process is performed. The alignment key is located in the scribe lane area, thus preventing the degree of integration of a semiconductor chip from decreasing.

### SUMMARY

An embodiment of the present disclosure may provide for a method of manufacturing a semiconductor device. The method may include forming a photoresist over a first structure, forming a photoresist pattern by removing a portion of the photoresist through a mask including a mask opening, wherein the mask opening includes a light-blocking pattern and a light-transmitting area, forming, by etching the first structure according to the photoresist pattern, a target opening corresponding to the mask opening and an auxiliary pattern corresponding to the light-blocking pattern of the mask opening, wherein the target opening is formed to have a first depth, wherein the auxiliary pattern is formed to have a second depth that is shallower than the first depth, and wherein the auxiliary pattern is located in the target opening and is implemented as a part of the first structure, and forming an alignment key by removing the auxiliary pattern from within the target opening.

An embodiment of the present disclosure may provide for a mask. The mask may include a mask opening, a light-blocking pattern, in the mask opening, configured to block light, and a light-transmitting area, in the mask opening, in which the light is transmitted. The light-blocking pattern partitions the light-transmitting area into at least two parts or is partitioned into at least two parts by the light-transmitting area, and the light-blocking pattern and the light-transmitting area are formed within a first region including a center of the mask opening.

### BRIEF DESCRIPTION OF THE DRAWINGS

FIG. 1 is a view illustrating the structure of a semiconductor device according to an embodiment of the present disclosure.

FIG. 2 is a view illustrating the structure of a semiconductor device according to an embodiment of the present disclosure.

FIGS. 3A to 3E are views illustrating a method of manufacturing a semiconductor device using a mask according to an embodiment of the present disclosure.

FIGS. 4A to 4C are diagrams illustrating examples of a mask according to an embodiment of the present disclosure.

FIG. 5 is a diagram illustrating a memory card system to which a memory device according to the present disclosure is applied.

FIG. 6 is a diagram illustrating a solid state drive (SSD) system to which a memory device according to the present disclosure is applied.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

Hereinafter, various embodiments of the present disclosure will be described in detail with reference to the accompanying drawings in which embodiments of the present disclosure are shown so that those skilled in the art to which the present disclosure pertains can easily practice the technical spirit of the present disclosure.

Various embodiments of the present disclosure are directed to a mask capable of preventing or reducing the occurrence of defects in an alignment key due to insufficient etching when the alignment key is formed, and a method of manufacturing a semiconductor device using the mask.

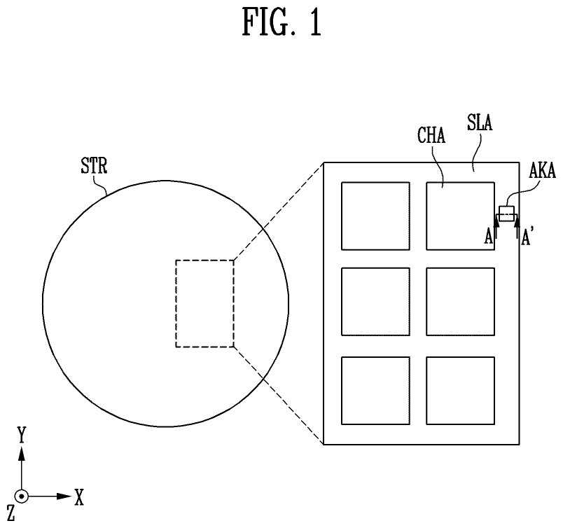

FIG. 1 is a view illustrating the structure of a semiconductor device according to an embodiment of the present disclosure.

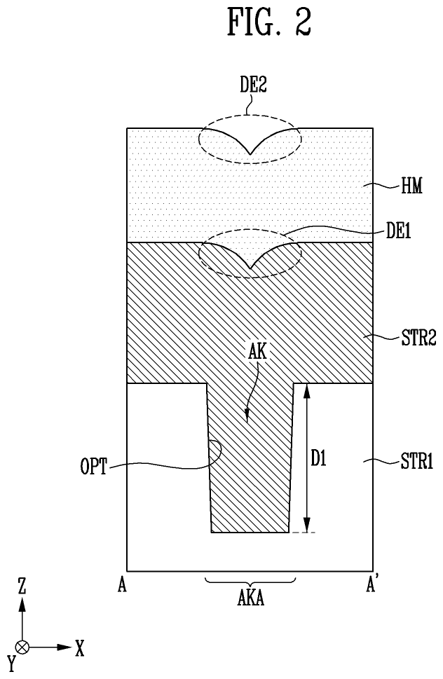

The semiconductor device may include a structure STR. For example, the structure STR may include a substrate (e.g., a silicon wafer, a silicon germanium (SiGe) wafer, a silicon-on-insulator (SOI) wafer, or the like) and material patterns formed on the substrate. The structure STR may include at least two sub-structures. The sub-structures will be described later with reference to FIG. 2.

Referring to FIG. 1, the structure STR may include chip areas CHA and a scribe lane area SLA. For example, the structure STR may include the chip areas CHA and the scribe lane area SLA surrounding the chip areas CHA.

The chip areas CHA may be areas in which semiconductor chips are formed. The chip areas CHA may be arranged in an X direction and a Y direction. Through a semiconductor integration process performed on the chip areas CHA, the semiconductor chips may be respectively formed. The semiconductor chips respectively formed in the plurality of chip areas CHA may be substantially identical to each other. After the semiconductor integration process is completed on the substrate, the structure STR may be separated into respective chip areas CHA, and thus, the semiconductor chips respectively formed in the chip areas CHA may be separated from each other.

The scribe lane area SLA may be disposed outside of the chip areas CHA. For example, the scribe lane area SLA may be disposed between the chip areas CHA. After the semiconductor integration process is completed, the scribe lane area SLA may be cut out during a dicing process that separates the semiconductor chips. The structure STR may be cut along the scribe lane area SLA, thus enabling the chip areas CHA to be separated from each other. As a process for cutting the structure STR, a scheme, such as a sawing process using a blade, a laser process using a laser, or a stealth dicing process, may be used. In the scribe lane area SLA, a chip guard for protecting the chip areas CHA, an electric test pattern, a process monitoring pattern, and alignment keys may be disposed.

An alignment key area AKA may be defined in a portion of the scribe lane area SLA. The alignment key area AKA may be an area in which alignment keys are formed. Such an alignment key will be described later, with reference to FIG. 2.

Although six chip areas CHA are illustrated in FIG. 1 for convenience of description, this structure does not limit the scope of the present disclosure. For example, the structure STR may include seven or more chip areas CHA. Further, although one alignment key area AKA is illustrated as being included in the scribe lane area SLA in FIG. 1, this structure does not limit the scope of the present disclosure. The location and number of align key areas AKA included in the scribe lane area SLA may be modified in various ways. For example, the alignment key areas AKA may be formed at any location in the scribe lane area SLA around the chip areas CHA. In another embodiment, at least two alignment key areas AKA may be located to be adjacent to any one chip area CHA.

FIG. 2 is a view illustrating the structure of a semiconductor device according to an embodiment of the present disclosure. FIG. 2 is a sectional view taken along line A-A′ of FIG. 1.

Referring to FIG. 2, the semiconductor device may include at least two sub-structures. For example, the semiconductor device may include a first structure STR1 and a second structure STR2 on the first structure STR1. In the present disclosure, it may be understood that the first structure STR1 and the second structure STR2 are included in the sub-structures described in FIG. 1.

The first structure STR1 may include at least one material layer. In an embodiment, the first structure STR1 may include a stacked body in which first and second material layers are alternately stacked along a Z direction. The first structure STR1 may further include a substrate disposed under the stacked body. For example, each of the first material layers may be an interlayer insulating layer (e.g., an oxide layer), and each of the second material layers may be a conductive layer (e.g., tungsten (W), cobalt (Co), nickel (Ni), molybdenum (Mo), silicon (Si), polysilicon (Poly-Si)) or a sacrificial layer (e.g., a nitride layer). In an embodiment, the first structure STR1 might not include the stacked body. Embodiments of the material layers in the first structure STR1 described in the present disclosure do not limit the scope of the present disclosure.

The first structure STR1 may include an alignment key AK disposed in the alignment key area AKA. The alignment key AK may be disposed in the first structure STR1. The alignment key AK may extend from the top surface of the first structure STR1, which is in contact with the bottom surface of the second structure STR2, toward the bottom surface of the first structure STR1 in a downward direction (e.g., a direction opposite to a Z direction). The alignment key AK may be formed by etching the first structure STR1 to a certain depth from the top surface of the first structure STR1. For example, the alignment key AK may penetrate at least a portion of the first structure STR1. For example, when the first structure STR1 includes the stacked body that is stacked along the Z direction, the alignment key AK may penetrate at least a portion of the stacked body. In the present disclosure, the alignment key AK may include an overlay vernier. The alignment key AK may include a target opening OPT. The

target opening OPT may be formed to be depressed from the top surface of the first structure STR1 in a downward direction (e.g., the direction opposite to the Z direction). A portion of the first structure STR1 may be exposed through a sidewall and a bottom surface of the target opening OPT. The target opening OPT may be formed by etching a portion of the first structure STR1. For example, when the first structure STR1 includes the stacked body, the target opening OPT may be formed by etching at least some of the first and second material layers included in the stacked body. The target opening OPT may be formed to have a first depth

from the top surface of the first structure STR1. The depth (e.g., first depth D1) of the target opening OPT may correspond to the height of the alignment key AK. For example, when the first structure STR1 includes the stacked body, the first depth D1 may be equal to or greater than the height of the stacked body. That is, the target opening OPT may pass through the stacked body.

The second structure STR2 may be disposed on the first structure STR1. The second structure STR2 may include at least one material layer. For example, the second structure STR2 may include a stacked body in which first and second material layers are alternately stacked along the Z direction. Embodiments of the material layers in the second structure STR2 described in the present disclosure do not limit the scope of the present disclosure.

The second structure STR2 may fill the alignment key AK. The second structure STR2 may extend into the alignment key AK. The second structure STR2 may protrude downward toward into the alignment key AK. The second structure STR2 may be formed in the target opening OPT of the alignment key AK. For example, the alignment key AK may be filled with a portion of the second structure STR2 while the second structure STR2 is formed on the first structure STR1.

The second structure STR2 may have a first depression DE1 corresponding to the alignment key AK due to the second structure STR2 filling the alignment key AK. The first depression DE1, recessed in a downward direction (e.g., the direction opposite to the Z direction), may be formed in a region corresponding to the alignment key AK on the top surface of the second structure STR2. In an embodiment, the area of a region corresponding to the first depression DE1 may be equal to, less than, or greater than the cross-sectional area of the alignment key AK.

A hard mask HM may be disposed on the second structure STR2. For example, the hard mask HM may be made of an opaque material. The hard mask HM may have a second depression DE2 corresponding to the alignment key AK due to the hard mask HM filling the first depression DE1. The second depression DE2, recessed in a downward direction (e.g., the direction opposite to the Z direction), may be formed in a region corresponding to the alignment key AK on the top surface of the hard mask HM. In an embodiment, the area of a region corresponding to the second depression DE2 may be equal to, less than, or greater than the area of the region corresponding to the first depression DE1.

The location of the alignment key AK may be identified by using the second depression DE2 included in the hard mask HM. For alignment in processes that are performed after the hard mask HM is formed, the second depression DE2 may be used. For example, when the hard mask HM is opaque and the alignment key is formed to be flat, which leads to the hard mask HM being flat, it may be difficult to identify the location of the alignment key disposed below the hard mask HM. However, in the present disclosure, the alignment key AK may penetrate the first structure STR1, which in turn forms the first and second depressions DE1 and DE2, whereby the location of the alignment key AK may be estimated based on the location of the second depression DE2.

In order to form the second depression DE2 on the top surface of the hard mask HM, the cross-sectional area (e.g., the area on an XY plane) of the alignment key AK needs to be equal to or greater than a certain size, or the internal volume of the alignment key AK needs to be equal to or greater than a certain volume. For example, the cross-sectional area of the alignment key AK may be greater than the cross-sectional area of a cell plug included in the semiconductor device. When the cross-sectional area of the alignment key AK is less than the certain size or when the internal volume of the alignment key AK is less than the certain volume, the first depression DE1 or the second depression DE2 might not be formed or may be incompletely formed. Therefore, the alignment key AK in the present disclosure may be referred to as a plug large key.

However, in conventional technology, there is a case in which defects occur in the alignment key AK due to insufficient etching when the alignment key AK is formed. For example, when the cross-sectional area of the alignment key AK is greater than the cross-sectional area of the cell plug, it may be difficult to sufficiently etch the alignment key AK when an etchant determined to target the cell plug is used. When defects occur in the shape of the alignment key AK due to insufficient etching, the first and second depressions DE1 and DE2 might not be formed or may be incompletely formed, thus making it difficult to perform alignment using the alignment key AK.

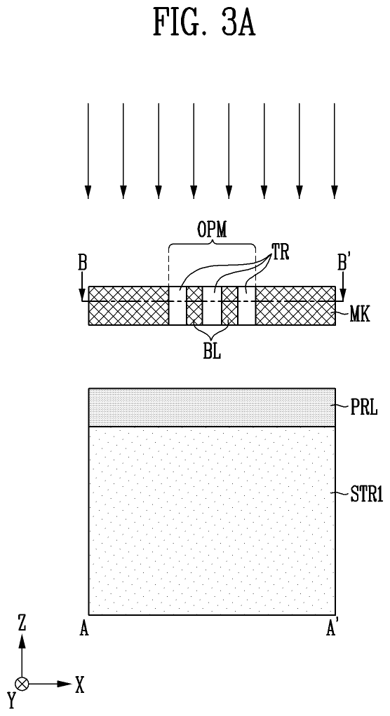

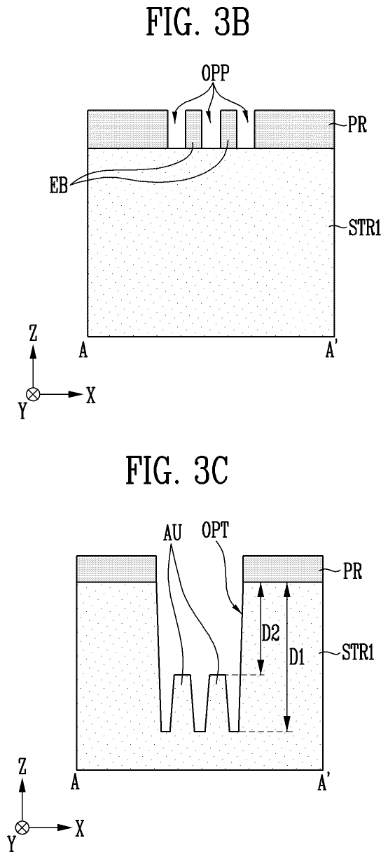

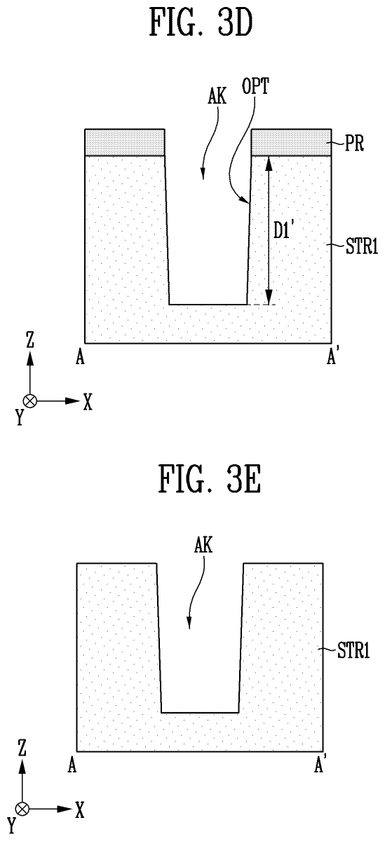

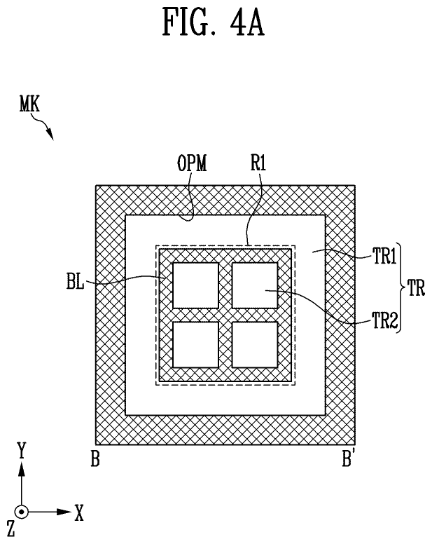

In the present disclosure, technology that is capable of reducing faults or defects from occurring in the alignment key AK due to insufficient etching is described. A detailed method of reducing or preventing the occurrence of defects in the alignment key AK will be described in detail below with reference to FIGS. 3A to 3E.

FIGS. 3A to 3E are views illustrating a method of manufacturing a semiconductor device using a mask according to an embodiment of the present disclosure. FIGS. 3A to 3E are sectional views taken along line A-A′ of FIG. 1.

Referring to FIG. 3A, a photoresist PRL may be formed on a first structure STR1. The photoresist PRL may cover the first structure STR1. The photoresist PRL may be formed of a material, chemical properties of which are changed by light.

A mask MK may be aligned on the first structure STR1 and the photoresist PRL. The mask MK may include a mask opening OPM, a light-blocking pattern BL in the mask opening OPM, and a light-transmitting area TR in the mask opening OPM. The mask MK may include at least one mask opening OPM. The light-blocking pattern BL may block light traveling from one direction to another direction through the mask MK. The light-transmitting area TR may transmit light traveling from one direction to another direction through the mask MK. For example, the mask MK may be made by forming an opaque material in a specific region of a transparent material (e.g., glass). The light-transmitting area TR may be an area in which the light-blocking pattern BL is not formed, rather than an empty space. An area in which the light-blocking pattern BL is not formed within the mask opening OPM may correspond to the light-transmitting area TR.

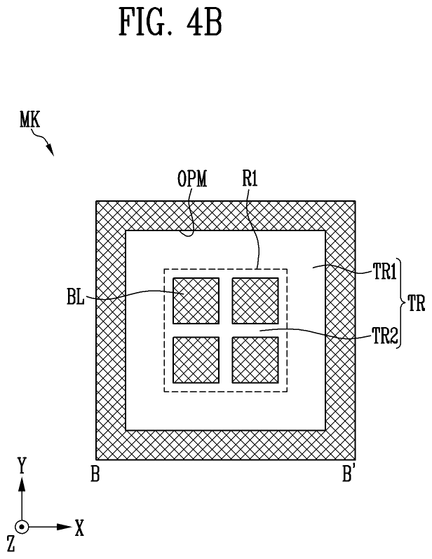

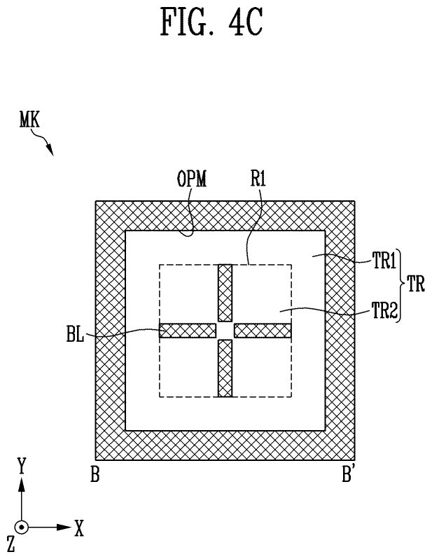

The light-blocking pattern BL may have a shape that partitions the light-transmitting area TR into at least two parts or a shape that is partitioned into at least two parts by the light-transmitting area TR, and the light-blocking pattern BL may be formed within a first region including the center of the mask opening OPM. Various embodiments in which the light-blocking pattern BL and the light-transmitting area TR are disposed in the mask opening OPM will be described in detail later with reference to FIGS. 4A to 4C.

Through the mask MK, the photoresist PRL may be exposed. In order to pattern the photoresist PRL, the photoresist PRL may be exposed through the mask MK. Over the mask MK, light may be applied to the mask MK and the photoresist PRL. The light may pass through the light-transmitting area TR, among areas of the mask opening OPM of the mask MK, and might not pass through the light-blocking pattern BL. Through the mask MK, a portion of the photoresist PRL may be exposed, and other portions of the photoresist PRL might not be exposed.

Referring to FIG. 3B, a portion of the photoresist PRL may be removed to form a photoresist pattern PR. When the exposed photoresist PRL is developed, a portion of the photoresist PRL may be removed. Of the photoresist PRL in FIG. 3A, an exposed region may be removed, and a region that is not exposed may remain in FIG. 3B. For example, the region of the photoresist PRL, corresponding to the light-transmitting area TR of the mask MK, may be removed. Further, a region of the photoresist PRL, corresponding to the light-blocking pattern BL of the mask MK, might not be removed. The photoresist PRL may be patterned based on the exposure and development of the photoresist PRL, and then the photoresist pattern PR may be formed.

The photoresist pattern PR may include photo-openings OPP corresponding to the light-transmitting area TR of the mask MK and may include barrier patterns EB corresponding to the light-blocking pattern BL of the mask MK. The photo-openings OPP may pass through the photoresist pattern PR. Through the photo-openings OPP, a portion of the top surface of the first structure STR1 may be exposed.

Referring to FIG. 3C, the first structure STR1 may be etched according to the photoresist pattern PR. The first structure STR1 may be etched by an etchant (e.g., plasma) supplied over the photoresist pattern PR. For example, a region of the first structure STR1, exposed through the photo-openings OPP, may be etched. Because the photoresist pattern PR functions as an etching barrier, the first structure STR1 exposed through the photo-openings OPP may be etched. Also, a region of the first structure STR1 (e.g., a region disposed under the barrier patterns EB) that is not exposed through the photo-openings OPP may also be etched. Generally, the region covered by the photoresist pattern PR might not be etched, but the present disclosure may be configured such that the region of the first structure STR1 that is not exposed through the photo-openings OPP may also be etched depending on the scheme, which will be described below. Furthermore, regions of the first structure STR1, which do not correspond to the photo-openings OPP and the barrier patterns EB, might not be etched. The heights of regions of the photoresist pattern PR, which do not correspond to the photo-openings OPP and the barrier patterns EB, may be reduced while a process of etching the first structure STR1 is being performed.

The first structure STR1 exposed by the photo-openings OPP may be etched, whereby a target opening OPT may be formed. The target opening OPT may have a first depth D1.

While the first structure STR1 is being etched according to the photoresist pattern PR, the barrier patterns EB may be removed. For example, the barrier patterns EB may be broken down or may collapse during the etching process of the first structure STR1. Therefore, the region of the first structure STR1, covered by the barrier patterns EB, may be etched to have a second depth D2. The second depth D2 may be shallower than the first depth D1.

Regions disposed below the barrier patterns EB having the second depth D2 may be referred to as auxiliary patterns AU. The auxiliary patterns AU may be disposed in the target opening OPT. The auxiliary patterns AU may be implemented as portions of the first structure STR1 remaining in the target opening OPT. Each auxiliary pattern AU may have a shape protruding from the bottom surface of the target opening OPT in an upward direction (e.g., Z direction). The height of each auxiliary pattern AU may correspond to the difference between the first depth D1 and the second depth D2. Although two auxiliary patterns AU are illustrated as equally having the second depth D2 in FIG. 3C, this is only an example, and does not limit the scope of the present disclosure. In an example, respective auxiliary patterns AU may have different depths as long as the depths are shallower than the first depth D1. In an example, any one auxiliary pattern AU may have a different depth depending on the location on the plane.

The target opening OPT may include a region in which the first structure STR1 is opened through the photo-openings OPP and a region that is opened by the barrier patterns EB, which are removed during the etching of the first structure STR1. The target opening OPT may correspond to the mask opening OPM of the mask MK. The auxiliary patterns AU may include a region that is less etched due to the barrier patterns EB within the target opening OPT, the region having the second depth D2. That is, a partial lower portion that is disposed below the barrier patterns EB in the first structure STR1 remains after only partial upper portions are etched. The auxiliary patterns AU may correspond to the light-blocking pattern BL of the mask MK. Each of the auxiliary patterns AU may have a shape protruding from the bottom surface of the target opening OPT in an upward direction (e.g., Z direction).

Generally, a portion of the first structure STR1, covered by the photoresist pattern PR, might not be etched, but the barrier patterns EB according to the present disclosure are removed during etching. Accordingly, portions of the first structure STR1, located under the barrier patterns EB, may be partially etched instead of remaining without any change.

Referring to FIG. 3D, as a process of etching the first structure STR1 according to the photoresist pattern PR progresses, the auxiliary patterns AU may be removed. Because the etchant is supplied to the first structure STR1 even after the barrier patterns EB are removed, the auxiliary patterns AU may be etched. For example, because the etchant reaches the region having the second depth D2 earlier than the region having the first depth D1, the auxiliary patterns AU may be etched and removed. Therefore, an alignment key AK including the target opening OPT may be formed. The alignment key AK might not include the auxiliary patterns AU. The target opening OPT may have a first depth D1′. The first depth D1′ of FIG. 3D may be equal to or greater than the first depth D1 of FIG. 3C.

Referring to FIG. 3E, the photoresist pattern PR on the first structure STR1 may be removed.

Furthermore, referring to FIG. 2 together with FIG. 3E, a second structure STR2 may be formed on the first structure STR1 in which the alignment key AK is formed, after the process of FIG. 3D. The second structure STR2 may fill the target opening OPT of the alignment key AK. The second structure STR2 may have a depression (e.g., first depression DE1) corresponding to the alignment key AK.

According to the method described with reference to FIGS. 3A to 3E, defects in the alignment key AK occurring due to insufficient etching may be reduced or prevented. While the process of etching the first structure STR1 according to the photoresist pattern PR is in progress, the etchant may be concentrated in the photo-openings OPP before the barrier patterns EB are removed. Therefore, the first structure STR1 may be etched to a sufficient depth (e.g., the first depth D1), whereby the target opening OPT may be formed. Further, while the process of etching the first structure STR1 according to the photoresist pattern PR is in progress, the portion of the first structure STR1, covered by the barrier patterns EB, may be etched after the barrier patterns EB are removed. Therefore, the auxiliary patterns AU etched to the second depth D2 may be formed in the target opening OPT, and the auxiliary patterns AU may also be etched through continuous etching.

The accuracy of alignment may be improved when the alignment key AK including the target opening OPT has the first depth D1. For example, because the etchant is concentrated in the photo-openings OPP, the accuracy of the location and shape of formation of the alignment key AK may be improved. Therefore, according to the present disclosure, defects in the alignment key AK may be reduced, and the accuracy of alignment using the alignment key AK may be improved.

FIGS. 4A to 4C are diagrams illustrating examples of a mask according to an embodiment of the present disclosure. FIGS. 4A to 4C are sectional views taken along line B-B′ of FIG. 3A.

FIGS. 4A to 4C illustrate examples of a mask MK for forming a photoresist pattern PR by patterning a photoresist PRL through the mask MK and for forming the alignment key AK by etching the first structure STR1 according to the photoresist pattern PR. A light-blocking pattern BL of the mask MK may be disposed such that at least portions of barrier patterns EB of the photoresist pattern PR are removed during an etching of the first structure STR1.

Referring to FIGS. 4A to 4C, the mask MK may include a mask opening OPM, a light-blocking pattern BL for blocking light in the mask opening OPM, and a light-transmitting area TR for transmitting light in the mask opening OPM. The light-blocking pattern BL may be formed in a first region R1 including the center of the mask opening OPM. The light-transmitting area TR may include a first light-transmitting area TR1 outside the first region R1 and at least one second light-transmitting area TR2 inside the first region R1. Within the first region R1, the light-blocking pattern BL may have a shape that partitions the light-transmitting area TR into at least two parts or a shape that is partitioned into at least two parts by the light-transmitting area TR. The boundary of the mask opening OPM may contact the first light-transmitting area TR1.

Referring to FIG. 4A, the mask MK may include at least two (e.g., four) second light-transmitting areas TR2. The light-blocking pattern BL may surround the at least two second light-transmitting areas TR2. The light-blocking pattern BL may be disposed between the first light-transmitting area TR1 and the second light-transmitting areas TR2. Further, the light-blocking pattern BL may be disposed between individual second light-transmitting areas TR2. The light-blocking pattern BL may include at least two sub-patterns coupled to each other, and the second light-transmitting areas TR2 may be disposed between the sub-patterns. For example, the light-blocking pattern BL may have a shape in which three sub-patterns extending in parallel in an X direction and three sub-patterns extending in parallel in a Y direction intersect or contact each other.

The at least two (e.g., four) second light-transmitting areas TR2 may be adjacent to each other in the X direction or the Y direction. Furthermore, the at least two second light-transmitting areas TR2 may be symmetrical to each other with respect to the center of the mask opening OPM. Furthermore, the four second light-transmitting areas TR2 may be disposed in a 2×2 array around the center of the mask opening OPM.

Referring to FIG. 4B, the mask MK may include a light-blocking pattern BL partitioned into at least two parts by a second light-transmitting area TR2. The light-blocking pattern BL may include at least two (e.g., four) sub-patterns separated from each other. The second light-transmitting area TR2 may be disposed between individual sub-patterns. The second light-transmitting area TR2 may surround the sub-patterns included in the light-blocking pattern BL. The sub-patterns of the light-blocking pattern BL may be spaced apart from each other by the second light-transmitting area TR2. The sub-patterns of the light-blocking pattern BL may be adjacent to each other in the X direction or the Y direction. The sub-patterns of the light-blocking pattern BL may be symmetrical to each other with respect to the center of the mask opening OPM. For example, the sub-patterns included in the light-blocking pattern BL may be disposed in a 2×2 array around the center of the mask opening OPM.

When the photoresist PRL is patterned according to the mask MK of FIG. 4B, the area of the barrier patterns EB is larger than that shown in FIG. 4A or 4C, and thus all barrier patterns EB are not removed, but only portions of the barrier patterns EB adjacent to the photo-openings OPP may be removed during the etching of the first structure STR1. Alternatively, all barrier patterns EB may be removed depending on the sizes of respective sub-patterns of the light-blocking pattern BL.

Referring to FIG. 4C, the mask MK may include a light-blocking pattern BL partitioned into at least two parts by a second light-transmitting area TR2. The light-blocking pattern BL may include at least two (e.g., four) sub-patterns separated from each other. The second light-transmitting area TR2 may be disposed between individual sub-patterns. The second light-transmitting area TR2 may surround the sub-patterns included in the light-blocking pattern BL. The sub-patterns of the light-blocking pattern BL may be spaced apart from each other by the second light-transmitting area TR2. The sub-patterns of the light-blocking pattern BL may be adjacent to each other in the X direction or the Y direction. The sub-patterns of the light-blocking pattern BL may be symmetrical to each other with respect to the center of the mask opening OPM. For example, each of the sub-patterns included in the light-blocking pattern BL may have a shape extending from a point, spaced apart from the center of the mask opening OPM by a certain distance, in the X direction (or the Y direction).

The mask MK, illustrated in each of FIGS. 4A to 4C, is one example, and various embodiments may be implemented in addition to the illustrated examples. In an example, the mask MK may be formed to include second light-transmitting areas TR2 partitioned into 3×3 or 4×4 parts by the light-blocking pattern BL. In an example, the mask MK may be formed such that the light-blocking pattern BL includes sub-patterns partitioned into 3×3 or 4×4 parts by the second light-transmitting area TR2. That is, the arrangement of the light-blocking pattern BL and the light-transmitting area TR included in the mask MK may be modified in various ways as long as conditions are satisfied, the conditions being that the barrier patterns EB can be removed to form auxiliary patterns AU and then the auxiliary patterns AU can be etched while the photoresist PRL is patterned through the mask MK and the first structure STR1 is etched through the photoresist pattern PR.

Furthermore, although FIGS. 3A to 3D and 4A to 4C are described on the assumption that the photoresist PRL has positive properties, the embodiments of the present disclosure may be equally applied except that a light-blocking area (e.g., an area outside the mask opening OPM and the light-blocking pattern BL) and the light-transmitting area TR, which are included in the mask MK, are inverted to each other when the photoresist PRL has negative properties.

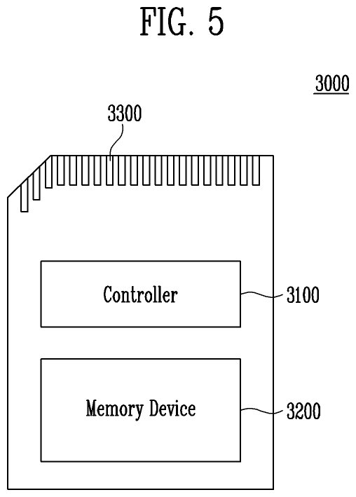

FIG. 5 is a diagram illustrating a memory card system to which a memory device according to an embodiment of the present disclosure is applied.

Referring to FIG. 5, a memory card system 3000 includes a controller 3100, a memory device 3200, and a connector 3300.

The controller 3100 may be coupled to the memory device 3200. The controller 3100 may access the memory device 3200. For example, the controller 3100 may control a program operation, a read operation, or an erase operation of the memory device 3200 or may control background operations of the memory device 3200. The controller 3100 may provide an interface between the memory device 3200 and a host. The controller 3100 may run firmware for controlling the memory device 3200. In an embodiment, the controller 3100 may include components, such as a random access memory (RAM), a processing unit, a host interface, a memory interface, and an error correction circuit.

The controller 3100 may communicate with an external device through the connector 3300. The controller 3100 may communicate with an external device (e.g., a host) based on a specific communication standard. For example, the controller 3100 may communicate with the external device through at least one of various communication standards, such as universal serial bus (USB), multimedia card (MMC), embedded MMC (eMMC), peripheral component interconnection (PCI), PCI-express (PCI-E), an advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). For example, the connector 3300 may be defined by at least one of the above-described various communication standards.

The memory device 3200 may include a plurality of memory cells.

The controller 3100 and the memory device 3200 may be integrated into a single semiconductor device to form a memory card. For example, the controller 3100 and the memory device 3200 may be integrated into a single semiconductor device and may then form a memory card, such as a PC card (personal computer memory card international association: PCMCIA), a compact flash card (CF), a smart media card (SM or SMC), a memory stick, a multimedia card (MMC, RS-MMC, MMCmicro or eMMC), a SD card (SD, miniSD, microSD, or SDHC), or universal flash storage (UFS).

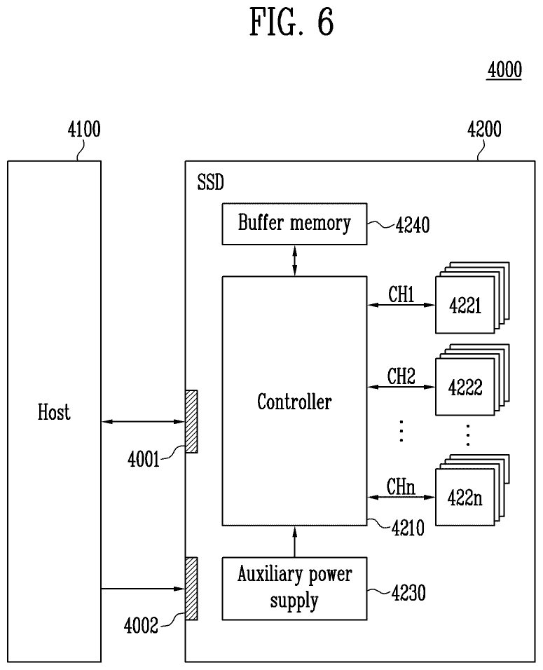

FIG. 6 is a diagram illustrating a solid state drive (SSD) system to which a memory device according to the present disclosure is applied.

Referring to FIG. 6, an SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. For example, the signal may indicate signals based on the interfaces of the host 4100 and the SSD 4200. For example, the signal may be a signal defined by at least one of interfaces, such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n may include a plurality of memory cells that store data. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied with a supply voltage from the host 4100 and may be charged. The auxiliary power supply 4230 may provide the supply voltage of the SSD 4200 when the supply of power from the host 4100 is not smoothly performed. For example, the auxiliary power supply 4230 may be located inside the SSD 4200 or located outside the SSD 4200. For example, the auxiliary power supply 4230 may be located on a main board and may also provide auxiliary power to the SSD 4200.

The buffer memory 4240 may function as a buffer memory of the SSD 4200. For example, the buffer memory 4240 may temporarily store data received from the host 4100 or data received from the plurality of memory devices 4221 to 422n or may temporarily store metadata (e.g., mapping tables) of the memory devices 4221 to 422n. The buffer memory 4240 may include volatile memories, such as DRAM, SDRAM, DDR SDRAM, and LPDDR SDRAM, or nonvolatile memories, such as FRAM, ReRAM, STT-MRAM, and PRAM.

The present disclosure may prevent or reduce the occurrence of a defect in an alignment key due to insufficient etching.

What is claimed is:

1. A method of manufacturing a semiconductor device, comprising:
forming a photoresist over a first structure;
forming a photoresist pattern by removing a portion of the photoresist through a mask including a mask opening, wherein the mask opening includes a light-blocking pattern and a light-transmitting area;
forming, by etching the first structure according to the photoresist pattern, a target opening corresponding to the mask opening and an auxiliary pattern corresponding to the light-blocking pattern of the mask opening, wherein the target opening is formed to have a first depth, wherein the auxiliary pattern is formed to have a second depth that is shallower than the first depth, and wherein the auxiliary pattern is located in the target opening and is implemented as a part of the first structure; and
forming an alignment key by removing the auxiliary pattern from within the target opening.

2. The method according to claim 1, wherein forming the photoresist pattern comprises:
exposing the photoresist by using the mask; and
forming the photoresist pattern including a photo-opening corresponding to the light-transmitting area and a barrier pattern corresponding to the light-blocking pattern by developing the exposed photoresist.

3. The method according to claim 2, wherein forming the alignment key comprises:
removing the barrier pattern while the first structure is etched according to the photoresist pattern.

4. The method according to claim 3,
wherein the auxiliary pattern is formed to have the second depth by removing at least a portion of the barrier pattern while the first structure is etched through the photo-opening, and
wherein the auxiliary pattern is formed to have a shape protruding upward from a bottom surface of the target opening, the bottom surface of the target opening having the first depth.

5. The method according to claim 1, wherein the light-blocking pattern is formed to have a shape that partitions the light-transmitting area into at least two parts or a shape that is partitioned into at least two parts by the light-transmitting area, and
wherein the light-blocking pattern and the light-transmitting area are formed within a first region including a center of the mask opening.

6. The method according to claim 5, wherein the light-transmitting area comprises a first light-transmitting area outside the first region and a second light-transmitting area inside the first region.

7. The method according to claim 6, wherein the light-blocking pattern partitions the second light-transmitting area into at least two parts and surrounds the second light-transmitting area partitioned into the at least two parts.

8. The method according to claim 6, wherein the light-blocking pattern is partitioned into at least two parts by the second light-transmitting area, and
wherein the second light-transmitting area is disposed between the at least two parts of the partitioned light-blocking pattern.

9. The method according to claim 1, wherein the first structure comprises a stacked body in which conductive layers and interlayer insulating layers are alternately stacked.

10. The method according to claim 1, further comprising, after forming the alignment key:
removing the photoresist pattern; and
forming a second structure over the first structure in which the alignment key is formed.

11. The method according to claim 10,
wherein forming the second structure comprises:
filling the target opening of the alignment key with the second structure, and
forming the second structure to have a depression corresponding to the alignment key.

12. A mask, comprising:
a mask opening;
a light-blocking pattern, in the mask opening, configured to block light; and
a light-transmitting area, in the masking opening, in which the light is transmitted,
wherein the light-blocking pattern partitions the light-transmitting area into at least two parts or is partitioned into at least two parts by the light-transmitting area, and
wherein the light-blocking pattern and the light-transmitting area are formed within a first region including a center of the mask opening.

13. The mask according to claim 12, wherein the light-transmitting area comprises a first light-transmitting area outside the first region and a second light-transmitting area inside the first region.

14. The mask according to claim 13,
wherein the light-transmitting area comprises at least two second light-transmitting areas, and
wherein the light-blocking pattern is disposed between the first light-transmitting area and the second light-transmitting areas and between the second light-transmitting areas.

15. The mask according to claim 14, wherein the second light-transmitting areas are adjacent to each other in a first direction or in a second direction, the second direction intersecting the first direction.

16. The mask according to claim 14, wherein the second light-transmitting areas are symmetrical to each other with respect to the center of the mask opening.

17. The mask according to claim 13,
wherein the light-blocking pattern comprises at least two sub-patterns, and
wherein the second light-transmitting area is disposed between the sub-patterns.

18. The mask according to claim 17, wherein the sub-patterns are adjacent to each other in a first direction or in a second direction, the second direction intersecting the first direction.

19. The mask according to claim 17, wherein the sub-patterns are symmetrical to each other with respect to the center of the mask opening.
